(19) United States
(12) Patent Application Publication
(10) Pub. No.: US 2011/0223333 A1
(43) Pub. Date: Sep. 15, 2011

(54) METHOD OF TREATING CATALYST FOR NANOCARBON PRODUCTION AND METHOD OF MANUFACTURING NANOCARBON

(76) Inventors: Masashi Yamage, Yokohama-shi (JP); Naoya Hayamizu, Yokohama-shi (JP)

(21) Appl. No.: 13/047,207

(22) Filed: Mar. 14, 2011

(30) Foreign Application Priority Data
Mar. 15, 2010 (JP) 2010-058180

(51) Int. Cl. C23C 16/26; B01J 23/755; B01J 21/18; C23C 16/44; C23F 1/00; C23F 1/16; C23F 1/28; C23F 1/30; C23F 1/40; B82Y 40/00

(52) U.S. Cl. 427/249.1; 502/337; 502/185; 216/100; 216/108; 216/109; 977/891

(57) ABSTRACT

According to one embodiment, a method of treating catalyst for nanocarbon production comprises, bringing a surface of a catalytic material into contact with a chemical, the catalytic material containing a metallic material and being used to produce nanocarbon, corroding the surface of the catalytic material, and drying the surface of the catalytic material.

### CROSS-REFERENCE TO RELATED APPLICATIONS

This application is based upon and claims the benefit of priority from Japanese Patent Application No. 2010-058180, filed Mar. 15, 2010; the entire contents of which are incorporated herein by reference.

### FIELD

Embodiments described herein relate generally to a method of treating catalyst for nanocarbon production and a method of manufacturing nanocarbon.

### BACKGROUND

As methods of manufacturing nanocarbon, one for forming nanocarbon on a metal which serves as a catalytic material, an ark discharge method and a chemical vapor deposition (CVD) method are known. As a method for obtaining nanocarbon of high purity, the CVD method is used, in which nanocarbon is produced on the metal in a catalytic material containing metal. Known CVD methods include thermal CVD and plasma CVD combined with thermal CVD.

Examples of a known catalytic material for nanocarbon production include iron, nickel, cobalt, or alloys thereof. However, if these catalysts are used, it is not ensured to produce nanocarbon. Moreover, if nanocarbon is successfully produced, it will be small in quantity and unstable.

Accordingly, there are increasing demands for a nanocarbon production catalyst treatment method and method of manufacturing nanocarbon, which make it possible to easily produce a large quantity of nanocarbon in a short time without expensive equipment for the treatment.

### BRIEF DESCRIPTION OF THE DRAWINGS

FIG. 1 is a diagram illustrating a method of manufacturing nanocarbon according to a first embodiment;

FIG. 2 is an SEM image showing the condition of the surface of a catalytic material prior to a chemical surface treatment where iron is used as the catalytic material in the method of manufacturing nanocarbon;

FIG. 3 is an AFM image showing the condition of the surface of a catalytic material prior to a chemical surface treatment where iron is used as the catalytic material in the method of manufacturing nanocarbon;

FIG. 4 is an SEM image showing the condition of the surface of a catalytic material after a chemical surface treatment where iron is used as the catalytic material in the method of manufacturing nanocarbon;

FIG. 5 is an AFM image showing the condition of the surface of a catalytic material after a chemical surface treatment where iron is used as the catalytic material in the method of manufacturing nanocarbon;

FIG. 6 is a graph representing a quantity of nanocarbon produced by the method of manufacturing nanocarbon using iron as the catalytic material;

FIG. 7 is an SEM image showing the condition of the surface of a catalytic material prior to chemical surface treatment where Invar is used as the catalytic material in a method of manufacturing nanocarbon according to a second embodiment;

FIG. 8 is an AFM image showing the condition of the surface of the catalytic material prior to chemical surface treatment where Invar is used as the catalytic material in the method of manufacturing nanocarbon;

FIG. 9 is an SEM image showing the condition of the surface of a catalytic material after chemical surface treatment where Invar is used as the catalytic material in a method of manufacturing nanocarbon;

FIG. 10 is an AFM image showing the condition of the surface of the catalytic material after chemical surface treatment where Invar is used as the catalytic material in the method of manufacturing nanocarbon;

FIG. 11 is a graph representing a quantity of nanocarbon produced by the method of manufacturing nanocarbon using Invar as the catalytic material;

FIG. 12 is an SEM image showing the condition of the surface of a catalytic material prior to chemical surface treatment where Kovar is used as the catalytic material in the method of manufacturing nanocarbon;

FIG. 13 is an SEM image showing the condition of the surface of a catalytic material after chemical surface treatment where Kovar is used as the catalytic material in the method of manufacturing nanocarbon;

FIG. 14 is a graph representing a quantity of nanocarbon produced by a method of manufacturing nanocarbon according to a third embodiment, using Kovar as the catalytic material; and

FIG. 15 is an SEM image showing nanocarbon formed on the corresponding catalytic materials in the respective embodiments.

### DETAILED DESCRIPTION

A method of treating catalyst for nanocarbon production according to one embodiment includes: bringing a surface of a catalytic material containing a metallic material and used to produce nanocarbon into contact with a chemical; corroding the surface of the catalytic material; and drying the surface of the catalytic material.

### First Embodiment

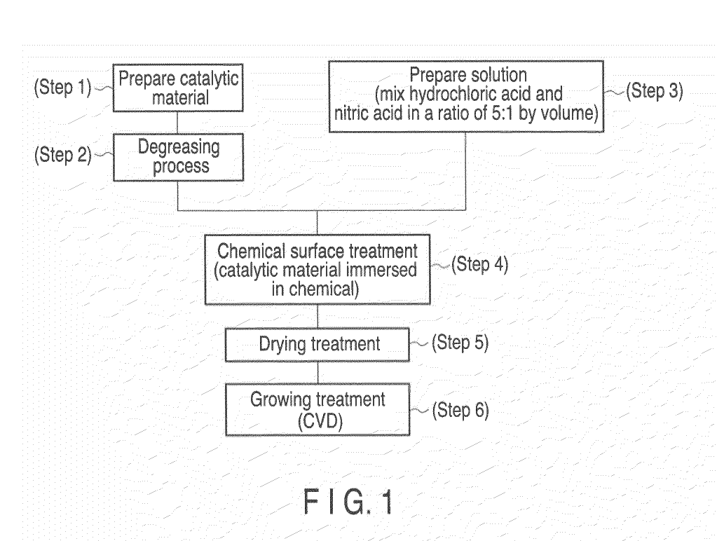

Referring to FIGS. 1, 2, 3, 4, 5, and 6, a method of treating catalyst for nanocarbon production and a method of manufacturing nanocarbon according to a first embodiment will be described.

FIG. 1 is a diagram illustrating steps in the method of manufacturing nanocarbon according to the present embodiment. This method includes: growing nanocarbon on a catalytic material (production treatment step): and corroding the surface of the catalytic material by means of a chemical surface treatment prior to the growing process (chemical treatment step).

Nanocarbon herein refers to, for example, a carbon material of minuscule size. Representative examples of such materials include carbon black, carbon nanotube, carbon nanocoil, fullerene, etc. For example, carbon nanotube is a fibrous substance formed from carbon as its main component. A carbon nanotube has an axial length that is ten or more times greater than the diameter thereof. For example, the diameter and length of a carbon nanotube are approximately several nm to 100 nm and several μm respectively.

As shown in FIG. 1, a metal plate is prepared for use as a catalytic material C1 (i.e., a nanocarbon production catalyst) (step 1). The catalytic material is appropriately determined according to the quantity and/or type of carbon material to be grown and/or various conditions pertaining to the device or devices to be used. In the present embodiment, a rectangular iron plate is used as an example.

Subsequently, a degreasing process is preformed by ultrasonically washing catalytic material C1 with acetone (step 2).

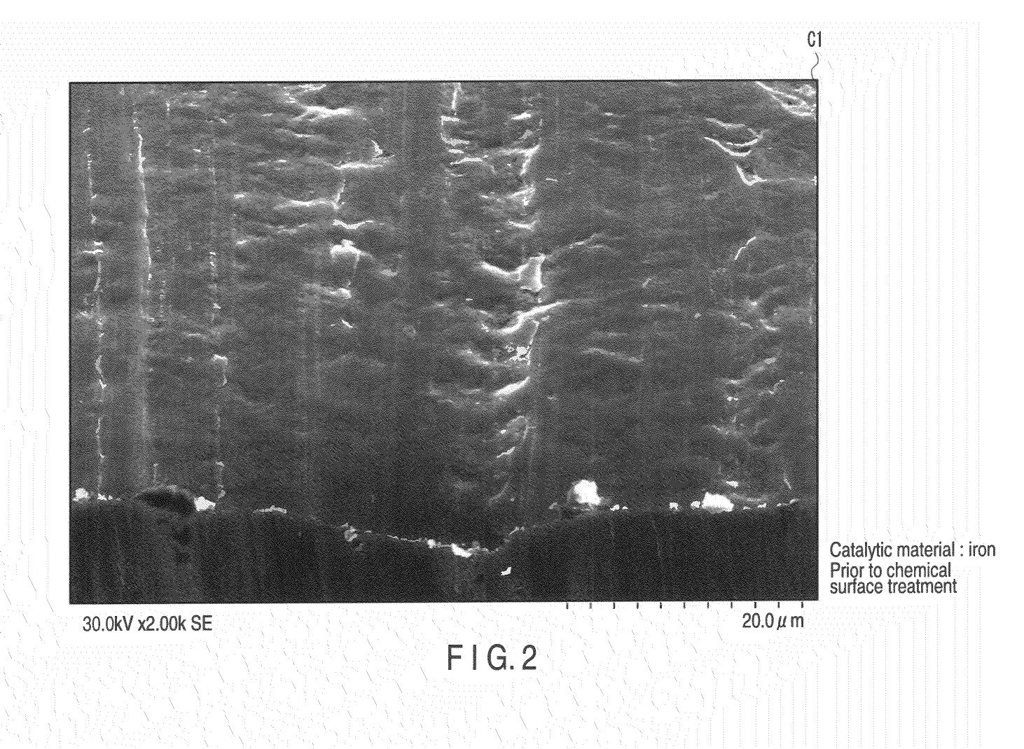

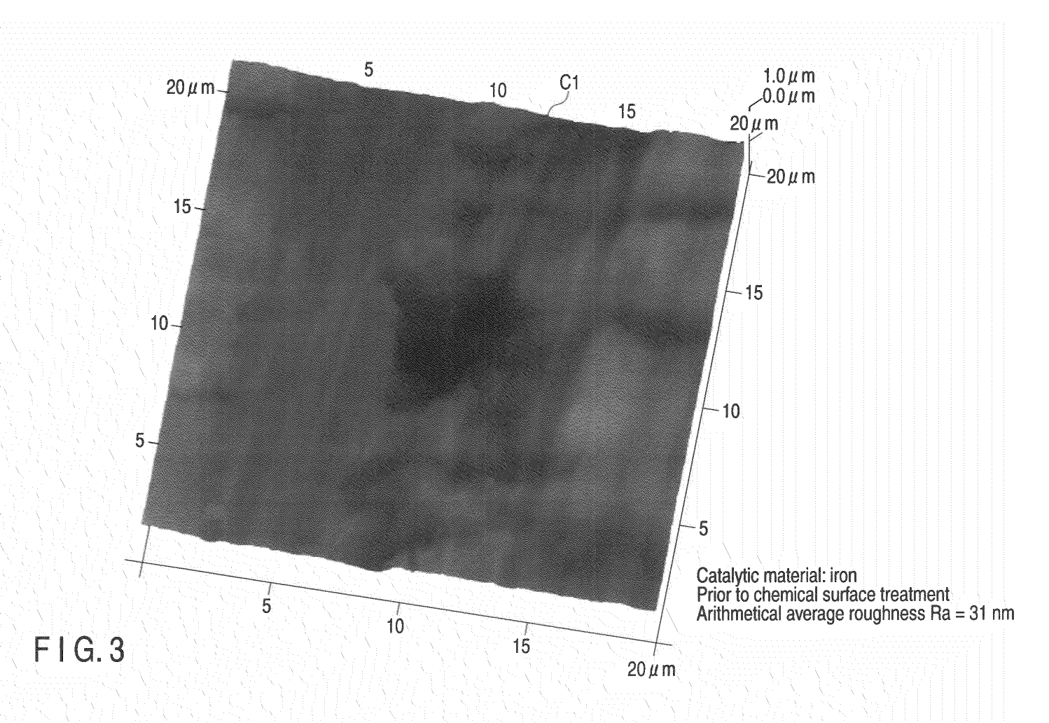

FIGS. 2 and 3 show the condition of the surface of catalytic material C1 in step 2 prior to the chemical surface treatment. That is, FIG. 2 is a scanning electron microscope (SEM) image showing the condition of the surface of catalytic material C1 prior to the chemical surface treatment, and FIG. 3 is an atomic force microscope (AFM) image showing the condition of the surface of catalytic material C1 prior to the chemical surface treatment.

At this time, an oxide film is formed on the surface of catalytic material C1 and, as shown in FIGS. 2 and 3, the surface of catalytic material C1 is flat. The arithmetical average roughness of the surface is Ra=31 nm.

Meanwhile, as a chemical, a solution is prepared, for example, by mixing hydrochloric acid and nitric acid in a ratio of 5:1 by volume and leaving the mixture for 20 minutes (step 3). This ratio is appropriate for etching nickel (Ni).

Subsequently, the chemical surface treatment is carried out by bringing the surface of catalytic material C1 into contact with the chemical, thereby corroding the surface (step 4). In this embodiment, catalytic material C1 is immersed in the chemical. An appropriate immersion time is determined according to the material. Here, catalytic material C1 is immersed for, for example, 120 seconds. By virtue of the chemical surface treatment, the metal is etched by the chemical. The effectiveness of etching includes increasing the surface roughness resulting from non-uniform etching, and removing oxide film from the surface. The mechanism resulting in increased roughness varies from material to material. The mechanism may be caused by, for example, etching that locally progresses due to the difference in etching rate between the surface oxide film and the metal material, namely, catalytic material C1. If an alloy is used and the etching rate differs among the metal types, the mechanism may be caused by galvanic corrosion (e.g., electrochemical corrosion, or corrosion by the effect of a battery) of the metals.

Subsequently, drying treatment is carried out, in which catalytic material C1 taken out from the chemical after the chemical surface treatment is dried by nitrogen blowing (step 5).

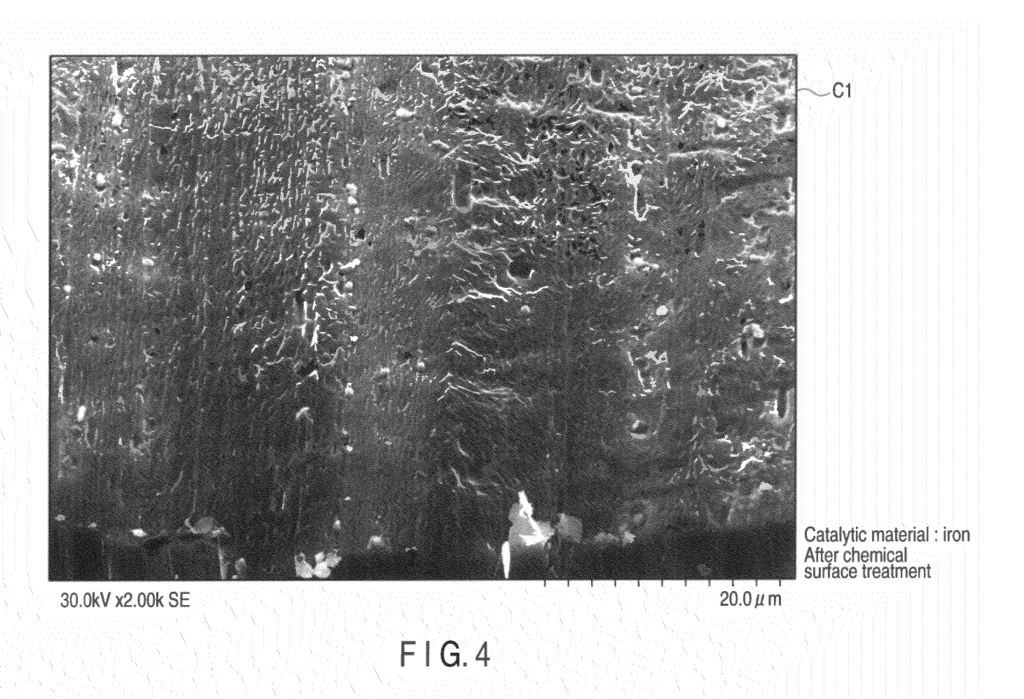

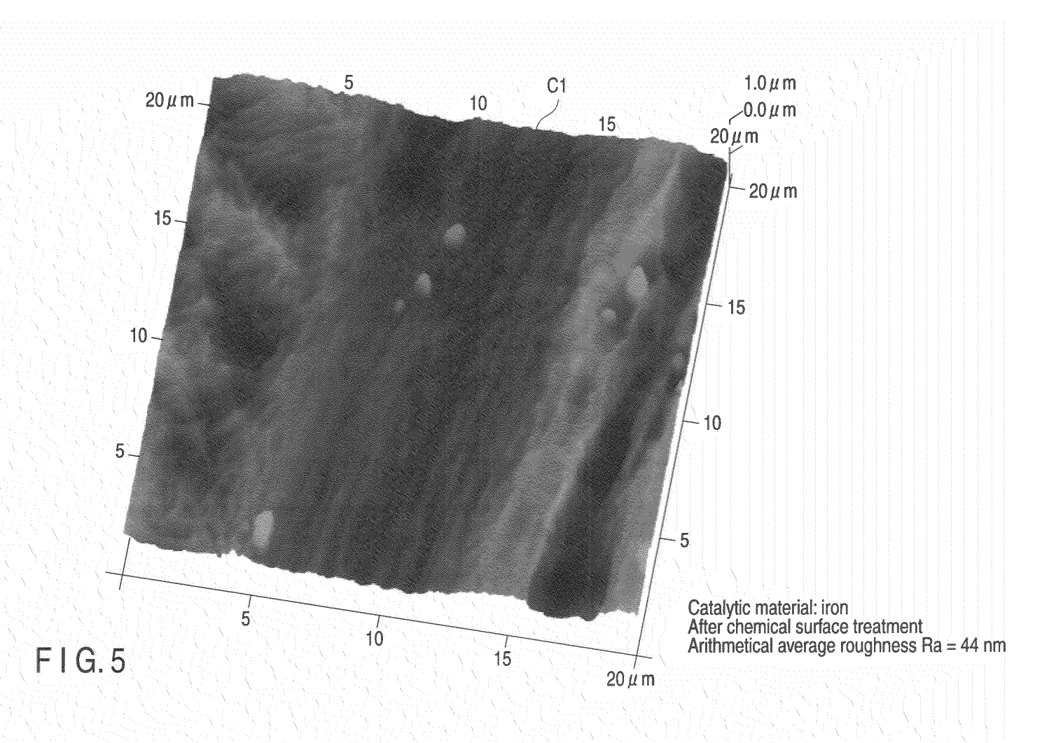

FIGS. 4 and 5 show the condition of the surface of catalytic material C1 at this stage after chemical surface treatment. That is, FIG. 4 is an SEM image showing the condition of the surface of catalytic material C1 after chemical surface treatment, and FIG. 5 is an AFM image showing the condition of the surface of catalytic material C1 after chemical surface treatment.

As shown in FIGS. 4 and 5, the surface of catalytic material C1 subjected to chemical surface treatment is corroded such that the surface of catalytic material C1 is slightly scraped, the surface of catalytic material C1 is a little roughened by the increase in roughness and removal of the oxide film from the surface, etc., and hence a large number of minute recesses and projections are formed on the surface. The arithmetical average roughness at this time is Ra=44 nm.

A large number of minute recesses and projections are formed on the surface after chemical surface treatment, compared to those on the surface prior to chemical surface treatment. These recesses and projections accelerate the production of fine catalytic particles of a size appropriate for the production of nanocarbon. In other words, the surface subjected to the chemical surface treatment is in a condition that makes it easy to form catalyst cores, from each of which nanocarbon grows. In addition, the chemical surface treatment removes factors that block catalytic activity, such as carbon soiling the surface of catalytic material C1 or natural oxide films on the surface. Accordingly, this yields great advantage in the stable production of a large quantity of nanocarbon.

Next, as a growing treatment (i.e., a production treatment step), the iron plate, namely catalytic material C1, is set in a chemical vapor deposition (CVD) device to be subjected to CVD treatment (step 6). Thus, a large quantity of nanocarbon is produced on the surface of the catalytic material.

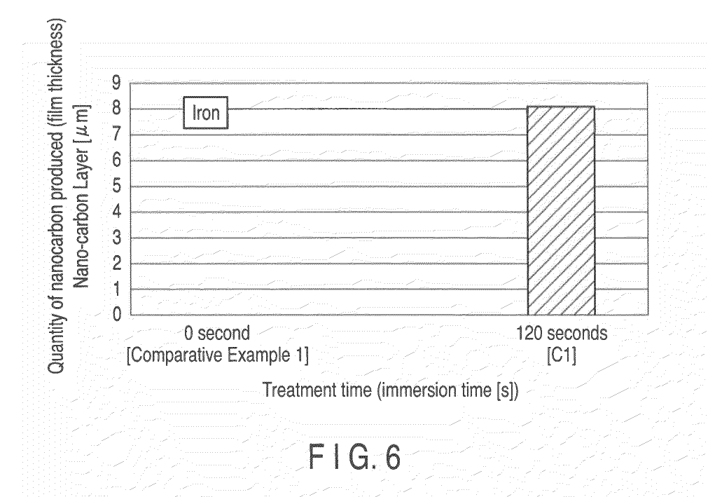

FIG. 6 is a graph showing a comparison between the quantity of nanocarbon produced in Comparative Example 1 where chemical surface treatment is not carried out (a treatment time of zero) and that produced when chemical surface treatment is carried out for 120 seconds. In this case, the film thickness (μm) of a nanocarbon layer formed on the surface of the catalytic material is taken to indicate the quantity of nanocarbon produced.

As FIG. 6 shows, whereas no nanocarbon is produced in Comparative Example 1 where chemical surface treatment is not carried out, an approximately 8-μm thick nanocarbon film is produced where chemical surface treatment is carried out. It is clear that chemical surface treatment increases nanocarbon production, compared to the case where such treatment is not carried out.

Nanocarbon thus produced by the method of manufacturing nanocarbon according to the present embodiment can be used for various purposes. As an example utilizing the physical dimensions of nanocarbon, it may be used in a cantilever that has a carbon nanotube at its leading end. In addition, since nanocarbon gathered together provides a large surface area within a limited space, it may be used as, for example, a bearing member of a metal nanoparticle catalyst. Further, conductive nanocarbon features both its physical dimensions and its ability to carry electric charges. By virtue of these two features, conductive nanocarbon may be used in, for example, an electronic device or electric circuit element in a micro-electromechanical system (MEMS); alternatively, one or more carbon nanotubes may be used as a channel or wire; alternatively, a carbon nanocoil may be used as a coil. Additionally, a large quantity of carbon black or carbon nanotubes may be added to a polymeric material and thereby used in manufacturing a conductive material while maintaining the polymeric material's properties of being easily processed. In this case, the meaning of “conductive” includes “semiconductive” and “electrically controllable.” Further, an electromagnetic radiation shield material or electromagnetic radiation absorber in which carbon nanotubes or carbon nanocoils are added to a polymeric material may be used in an electronic apparatus to be shielded from external electronic radiation, such as a personal computer or cellular phone components, or may be used in an electronic apparatus to prevent electromagnetic radiation from leaking out, such as a display or audio apparatus.

The method of treating catalyst for nanocarbon production and method of manufacturing nanocarbon according to the present embodiment yield advantage as described below. Specifically, the surface of a catalytic material for stably obtaining a large quantity of nanocarbon produced can be treated in a short time using inexpensive equipment. A method for heating a catalyst to, for example, 500 to 1000° C. and a method for treating a catalyst with hydrogen plasma require a specialized, expensive apparatus, making it difficult to reduce costs. However, the present embodiment easily and greatly increases nanocarbon production simply by immersing a catalytic material in a chemical for a short time. Accordingly, nanocarbon production can be easily and stably increased in a short time at low cost.

It should be understood that the invention is not limited to the embodiment described above, and that various changes and modifications of the components may be made in the invention without departing from the spirit and scope thereof. For example, the first embodiment described above uses iron as a catalytic material C1 but it may be another metal or a mixture including nonmetals. Examples of a catalytic material generally used are iron-nickel or materials containing cobalt.

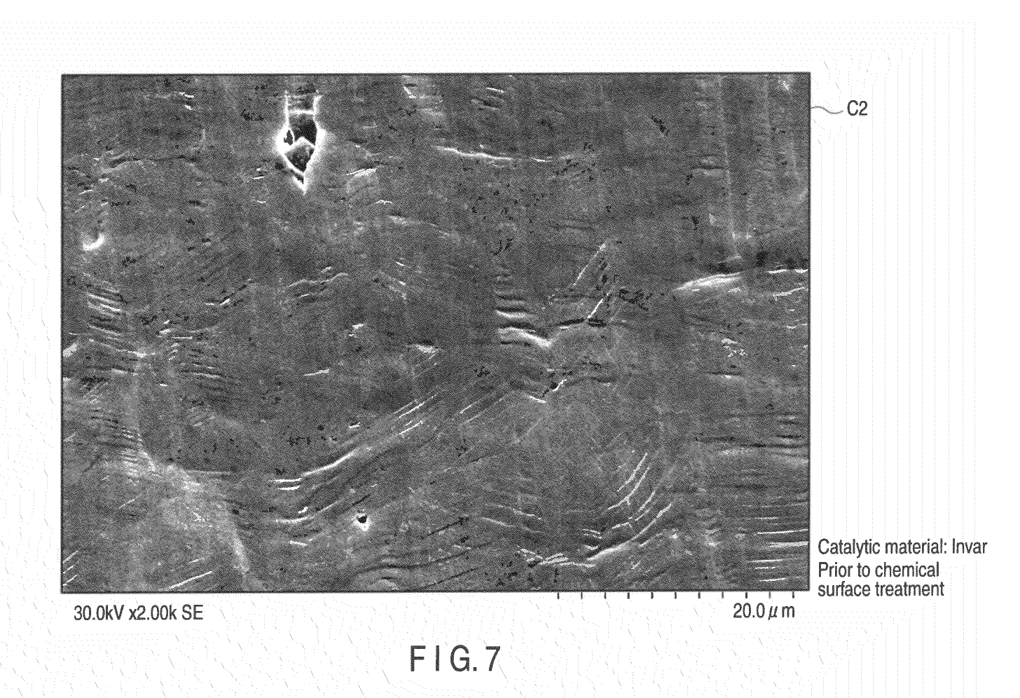

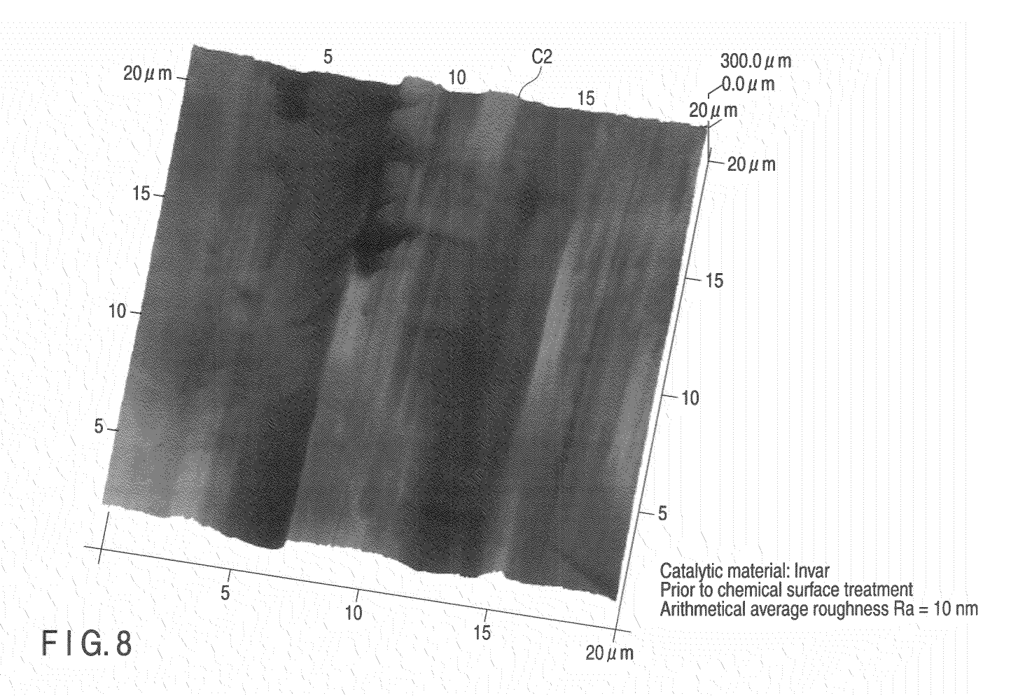

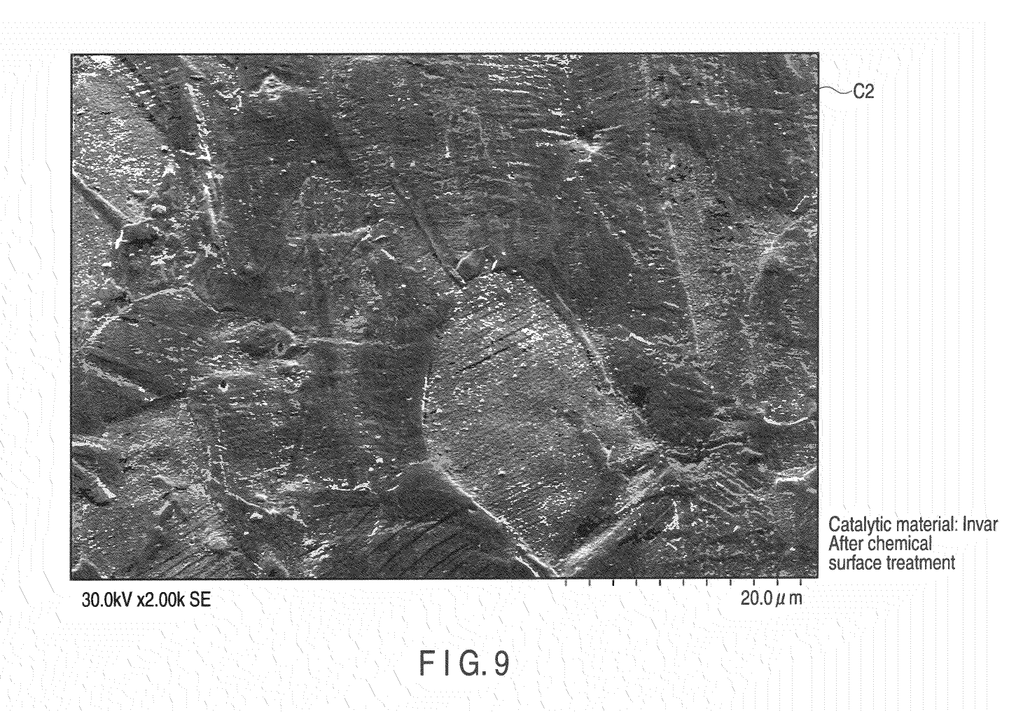

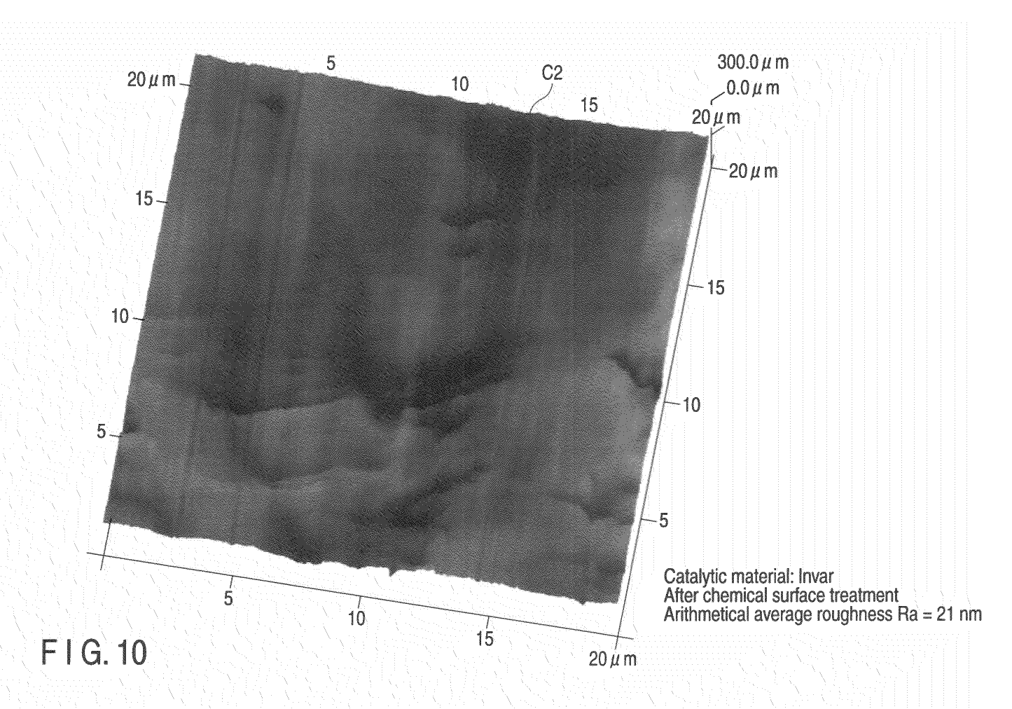

For example, FIGS. 7, 8, 9, 10, and 11 show another embodiment in which a plate-like member made of Invar is used as a catalytic material C2. Treatment steps in the nanocarbon manufacturing method are identical to those in the first embodiment described above. In addition, conditions for treatment in chemical surface treatment are identical to those in the first embodiment, and a solution containing hydrochloric acid and nitric acid mixed in a ratio of 5:1 is used. As shown in the SEM and AFM images prior to chemical surface treatment in FIGS. 7 and 8 respectively, the surface of catalytic material C2 prior to this treatment is smooth and has fewer recesses and projections. The arithmetical average roughness at this time is Ra=10 nm. On the other hand, as shown in the SEM and AFM images taken after the chemical surface treatment in FIGS. 9 and 10 respectively, the surface of catalytic material C2 after chemical surface treatment has a large number of minute recesses and projections. The arithmetical average roughness at this time is Ra=21 nm.

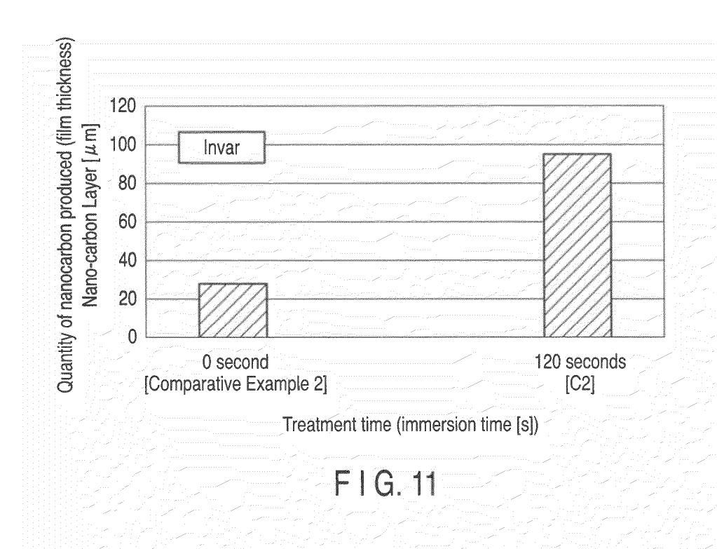

The present embodiment also yields advantage substantially identical to the first embodiment in which iron is used. Specifically, compared to Comparative Example 2 where chemical surface treatment is not carried out, as shown in FIG. 11, the present embodiment greatly increases production of nanocarbon when chemical surface treatment is carried out.

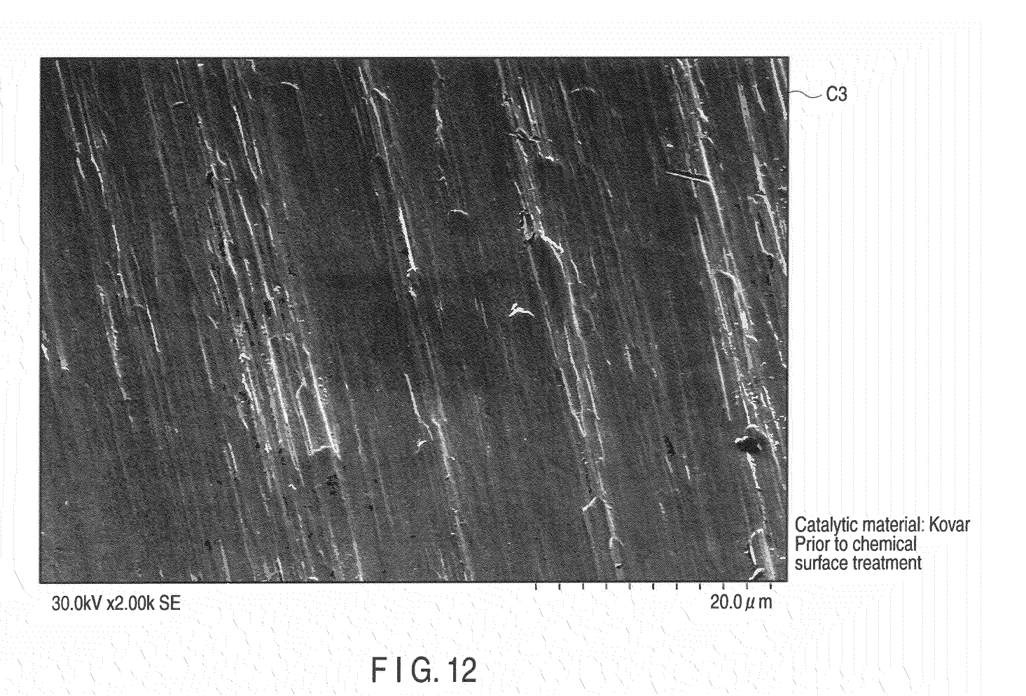

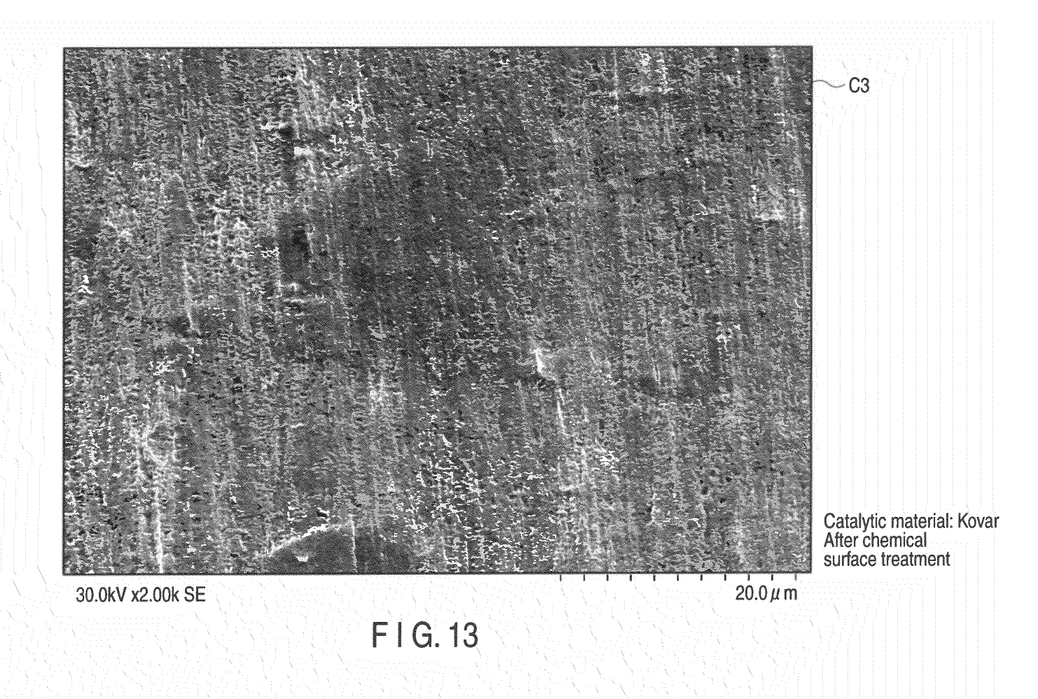

FIGS. 12, 13, and 14 show further embodiment in which a plate-like material made of Kovar is used as a catalytic material C3. Treatment steps in the method of manufacturing nanocarbon are identical to those in the foregoing embodiments. In addition, conditions for chemical surface treatment are identical to those in the first embodiment, and again a solution containing hydrochloric acid and nitric acid mixed in a ratio of 5:1 is used. In this embodiment, catalytic material C3 is immersed in the chemical for 120 seconds. As shown in FIG. 12, the surface of catalytic material C3 prior to chemical surface treatment is smooth with fewer recesses and projections. On the other hand, as shown in FIG. 13, the surface of catalytic material C3 after chemical surface treatment has a large number of minute recesses and projections.

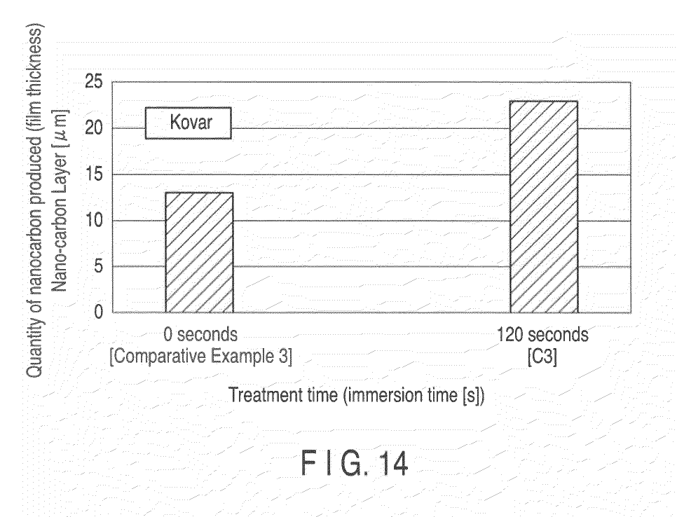

The present embodiment also yields advantages substantially identical to the first embodiment in which iron is used. Specifically, compared to Comparative Example 3 where chemical surface treatment is not carried out, as shown in FIG. 14, the present embodiment greatly increases production of nanocarbon when chemical surface treatment is carried out.

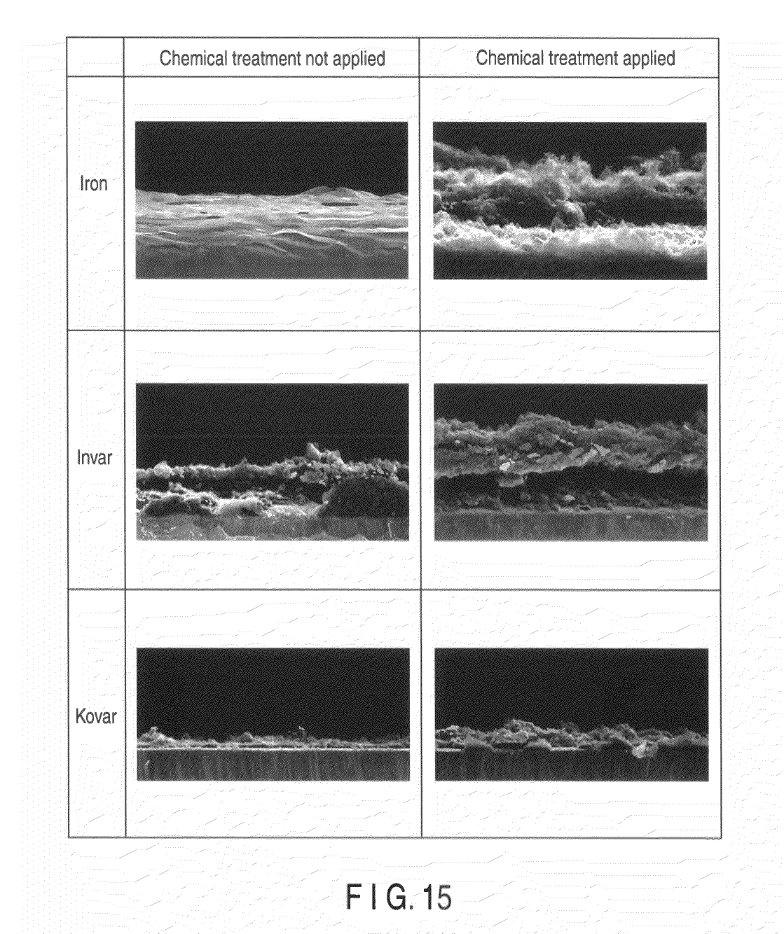

FIG. 15 shows SEM images of nanocarbon formed on the corresponding catalytic materials in the respective embodiments. It is apparent from these that the quantities of nanocarbon produced differ depending on whether chemical treatment has been applied or not.

Alternatively, the use of Incoloy, constantan, or Steel Use Stainless (SUS) stainless steel for use as a catalytic material is also advantageous.

The chemical is not limited to the forgoing embodiments either and it may be substituted with other chemicals as necessary, according to requirements for, for example, a catalytic material. Chemicals containing hydrochloric acid, nitric acid, sulfuric acid, hydrofluoric acid, phosphoric acid, hydrogen peroxide, ammonium hydroxide, or ammonium persulfate may be used. In particular, a solution containing hydrochloric acid and nitric acid mixed is highly effective for nickel.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of treating catalyst for nanocarbon production comprising:
bringing a surface of a catalytic material into contact with a chemical, the catalytic material containing a metallic material and being used to produce nanocarbon;
corroding the surface of the catalytic material; and
drying the surface of the catalytic material.

2. The method of claim 1, wherein the metallic material is iron, Invar, Kovar, stainless steel, nickel or an alloy thereof.

3. The method of claim 1, wherein the chemical includes at least hydrochloric acid, nitric acid, sulfuric acid, hydrofluoric acid, phosphoric acid, hydrogen peroxide, ammonium hydroxide, or ammonium persulfate.

4. The method of claim 1, wherein the chemical is a solution containing hydrochloric acid and nitric acid mixed in a ratio of 5:1 by volume.

5. A method of manufacturing nanocarbon comprising:
bringing a surface of a catalytic material into contact with a chemical, the catalytic material containing a metallic material and being used to produce nanocarbon;
corroding the surface of the catalytic material; and
drying the surface of the catalytic material; and
performing a chemical vapor deposition (CVD) method to produce nanocarbon on the surface of the catalytic material.

6. The method of manufacturing nanocarbon according to claim 5, wherein the metallic material is iron, Invar, Kovar, stainless steel, nickel or an alloy thereof.

7. The method of claim 5, wherein the chemical includes at least hydrochloric acid, nitric acid, sulfuric acid, hydrofluoric acid, phosphoric acid, hydrogen peroxide, ammonium hydroxide, or ammonium persulfate.

8. The method of claim 5, wherein the chemical is a solution containing hydrochloric acid and nitric acid mixed in a ratio of 5:1 by volume.
